(19) United States
(12) Patent Application Publication
(10) Pub. No.: US 2007/0164299 A1
(43) Pub. Date: Jul. 19, 2007

(54) HEMT PIEZOELECTRIC STRUCTURES WITH ZERO ALLOY DISORDER

(76) Inventors: Hacene Lahreche, Paris (FR); Philippe Bove, Paris (FR)

Correspondence Address: WINSTON & STRAWN LLP;PATENT DEPARTMENT, 1700 K STREET, N.W., WASHINGTON, DC, 20006, US

(21) Appl. No.: 11/684,925

(22) Filed: Mar. 12, 2007

Related U.S. Application Data
(63) Continuation of application No. PCT/EP05/54559, filed on Sep. 13, 2005.
(63) Continuation-in-part of application No. 11/004,411, filed on Dec. 3, 2004.

(30) Foreign Application Priority Data
Sep. 13, 2004 (FR) FR 04 09674
Mar. 31, 2005 (FR) FR 05 03173

(51) Int. Cl. H01L 33/00

(52) U.S. Cl. 257/97

(57) ABSTRACT

Electronic circuits dedicated to high frequency and high power applications based on gallium nitride (GaN) suffer from reliability problems. The main reason is a non-homogenous distribution of the electronic density in these structures that originates from alloy disorders at the atomic and micrometric scale. This invention provides processes for manufacturing semiconducting structures based on nitrides of Group III elements (Bal, Ga, In)/N which are perfectly ordered along a preferred crystalline axis. To obtain this arrangement, the ternary alloy barrier layer is replaced by a barrier layer composed of alternations of binary alloy barrier layers. The lack of fluctuation in the composition of these structures improves electron transport properties and makes the distribution more uniform.

### CROSS-REFERENCE TO RELATED APPLICATIONS

This application is a continuation of International Application PCT/EP2005/054559 filed Sep. 13, 2005. This application is also continuation-in-part of U.S. application Ser. No. 11/004,411 filed Dec. 3, 2004. The entire content of each application is expressly incorporated herein by reference thereto.

### FIELD OF THE INVENTION

This invention generally relates to manufacturing semiconductor substrates for use in making electronic components. The technical domain of the invention may be defined in general as preparation of layers of semiconducting materials based on nitride on a support. In particular, the invention pertains to a piezoelectric semiconductor structure that includes a support substrate, a channel layer arranged on one side of the support substrate, and a barrier layer formed on the channel layer. The barrier layer preferably comprises alternating binary alloy layers of Type III-Type V semiconductor materials.

### BACKGROUND ART

Semiconductor structures based on nitrides (Type III elements) found in the periodic table occupy an increasingly important place in the electronic and optoelectronic fields. These materials can be used to manufacture High Electron Mobility Transistors (HEMTs) which are used in high frequency and high power electronic circuits.

FIG. 1 is an example of an HEMT having a semiconductor structure made of Type III-Type N materials, or nitrides of Type III elements (such as InN, GaN, or AlN). The structure includes a barrier layer 20 made of gallium and aluminum nitride (AlGaN) provided on a channel layer 21 made of gallium nitride (GaN) that is provided on a support 22. The HEMT transistor also comprises a source electrode 23 and a drain electrode 24 on the front face 25 of the barrier layer 20 of AlGaN, and a grid electrode 26 between the source electrode 23 and the drain electrode 24.

Due to the presence of aluminum in the AlGaN barrier layer 20, the prohibited energy band of the barrier layer is wider than that of the channel layer 21 of GaN. Silicon impurities in the AlGaN barrier layer 20 supply electrons to the crystal that tend to accumulate in a region 27 with the lowest potential (i.e., a quantum well), which is located just under the interface 28 between the AlGaN barrier layer 20 and the GaN channel layer 21. A sheet of electrons 27 forms a two-dimensional electron gas (2 DEG). The mobility of electrons in this gas is high since they are physically separated from the silicon atoms residing in the AlGaN barrier layer 20.

The first studies of Type III-Type N semiconductor structures were conducted during the 1970s, but the real advantage of this type of material only became clear after p-type conduction was obtained in a GaN channel layer, followed by marketing of blue diodes by Nichia Chemicals. Devices based on AlGaN/GaN structures with two-dimensional electron gases now have much better characteristics than corresponding products of other materials. Semiconductor structures based on Type III-Type N form a very innovative semiconductor system, and have the following specific features: a prohibited band width varying from 0.8 eV to 6.2 eV, the possibility of making continuous alloys of AlGaN, which enables the production of heterostructures with a large degree of freedom, and a very weak crystalline mesh parameter mismatch between gallium nitride (GaN) and aluminum nitride (AlN). Thus, complex structures can be made without creation of crystalline defects according to the following formula:
Δa/a=(a_{GaN}−a_{AlN})/a_{GaN}=1%;

wherein a_{GaN} is the mesh parameter of GaN, a_{AlN} is the mesh parameter of AlN, and Δa/a is the mesh parameter mismatch (a mesh parameter mismatch less than or equal to 1% is the sign of quasi-pseudomorphic coherent growth). Such a complex structure has excellent electronic properties (good mobility of electrons, high saturation speed, high breakdown field), excellent thermal and chemical stability, good thermal properties (dissipation of heat), and the presence of a strong polarization field to obtain large charge transfers in two-dimensional electron gases.

Therefore, semiconductor structures based on Type III-Type N materials exhibit better performance characteristics than semiconductor structures based on “classical” Type III-Type V materials, particularly with regard to the mobility of charge carriers and the charge density.

Mobility of Charge Carriers

From the point of view of structure fabrication, mobility and the current density per unit surface area of AlGaN/GaN structures are governed by four parameters. The parameters include the defect density in the layers, the surface roughness (RMS) and the chemical roughness at the AlGaN/GaN interface (alloy disorder in the AlGaN barrier layer), the distance from the electron gas to the interface (2 DEG) which can be modulated by inserting a spacer (undoped potential barrier) to limit diffusion of electrons at the interface), and the stress in the HEMT structure (in the AlGaN and GaN layers). The stress influences the piezoelectric field. It is noted that there is also an intense spontaneous polarization field in wurtzite heterostructures that participate in the charge transfer.

Charge Density

Exceptional charge transfers observed in AlGaN/GaN structures (nₛ˜1020−3×10¹³ cm⁻²) are induced by a particular polarization field: the piezoelectric polarization field. This is also referred to as a piezo-induced High Electron Mobility Transistor (Piezo-HEMT). AlGaN/GaN structures have a Wurtzite-type hexagonal structure. Piezo-electric polarization originates from the non-centro symmetry of this Wurtzite structure.

There are several models that describe the piezo-electric polarization phenomenon. The simplest is the Ambacher et al. model that is briefly summarized below with reference to FIG. 2. Starting from this model, it is possible to determine what material parameters have an influence on the charge density of transistor structures that are based on Type III-Type N based semiconductor materials.

FIG. 2 illustrates a structure having a front face 1 or growth face that is terminated with Ga and Al. This structure includes a support 2, a GaN channel layer 3, and an AlGaN barrier layer 4. The support 2 is a semiconductor or non-semiconductor material. For example, the support 2 may be made of SiC or Si. The GaN channel layer 3 is deposited on the front face 5 of the support 2. This GaN channel layer 3 is relaxed. The AlGaN barrier layer 4 is located on the front face 6 of the GaN channel layer 3. This AlGaN barrier layer 4 is stressed. The AlGaN barrier layer 4 is an AlₓGa₁₋ₓN type alloy where x represents the molar fraction of the AlₓGa₁₋ₓN alloy.

If there is no external electric field, the total polarization field P of an AlₓGa₁₋ₓN/GaN structure along an axis [0001] is equal to the sum of a spontaneous polarization field P_{SP} and a piezoelectric polarization field P_{PE} induced by stress in the AlₓGa₁₋ₓN barrier layer. The spontaneous polarization field P_{SP}(X) in the AlₓGa₁₋ₓN barrier layer is expressed as a function of spontaneous polarization constants of gallium nitride (GaN) and aluminum nitride (AlN). Assuming a linear variation:
P_{SP}(x)=−0.52x−0.029 C/m² (1)

where x represents the molar fraction of the AlₓGa₁₋ₓN alloy.

The sign of the spontaneous polarization field P_{SP} will depend on the polarity of the crystal. In the classical case of a substrate 1 for which the growth face is terminated by a gallium layer (such as aluminum or indium), the spontaneous polarization field P_{SP} is negative, in other words is opposite the growth axis [0001]. Therefore, the spontaneous polarization field P_{SP} points from the growth face 1 towards the support 2.

The piezoelectric polarization field P_{PE}(X) in the AlₓGa₁₋ₓN barrier layer is expressed as a function of piezoelectric constants e₃₃(x) and e₃₁(x) of the alloy AlₓGa₁₋ₓN calculated from the piezoelectric constants of GaN and AlN:
P_{PE}(x)=e₃₃(x)ε_{zz}+e₃₁(x)(εₓₓ+ε_{yy}) (2)

wherein x represents the molar fraction of the alloy AlₓGa₁₋ₓN, e₃₃(x) and e₁₃(x) are the piezo-electric constants of the AlₓGa₁₋ₓN alloy, and εₓₓ, ε_{yy} and ε_{zz} represent deformations of the length, width and height of the AlₓGa₁₋ₓN alloy.

The piezoelectric constants e₃₃(x) and e₁₃(x) of the AlₓGa₁₋ₓN are calculated from the piezoelectric constants e₃₃ and e₁₃ of GaN and the piezoelectric constant e₃₃ and e₁₃ of AlN. As an example, Table I herein provides piezoelectric constants of GaN and of AlN.

TABLE I
piezoelectric constants of GaN and AlN

| Material | P_{SP} (C/m²) | e₃₃ (C/m²) | e₃₁ (C/m²) |
|---|---|---|---|
| AlN | −0.081 | 1.46 | −0.60 |
| GaN | −0.029 | 0.73 | −0.49 |

If the deformations εᵢⱼ are developed in equation (2) as a function of the elastic constants Cij(x) of the AlₓGa₁₋ₓN alloy and the mesh parameters of the GaN channel layer and the AlₓGa₁₋ₓN barrier layer, then the result is:

$${P}_{PE} ( x ) = \frac{2 a ( x ) - {a}_{0}}{{a}_{0}} ( {e}_{31} ( x ) - {e}_{33} ( x ) \frac{{C}_{13} ( x )}{{C}_{33} ( x )} ) \qquad ( 3 )$$

where in a₀ represents the mesh parameter of GaN, a(x) represents the mesh parameter of the AlₓGa₁₋ₓN alloy, and C₁₃(x) and C₃₃(x) represent the elastic constants of the AlₓGa₁₋ₓN alloy.

The elastic constants C₁₃(x) and C₃₃(X) of the AlₓGa₁₋ₓN alloy are calculated starting from elastic constants C₁₃ and C₃₃ of GaN and AlN assuming a linear variation as a function of x. The values of the elastic constants C₁₃ and C₃₃ of GaN and AlN commonly used in the literature are as given by Wright et al. These values agree well with experimental data, particularly data by Polian et al. for GaN. As an example, Table II provides the elastic constants of GaN and of AlN.

TABLE II
Elastic constants of GaN and AlN

| Material | C₁₃ | C₃₃ | Reference |
|---|---|---|---|
| AlN | 108 | 373 | Wright et al. |
| GaN | 103 | 405 | Wright et al. |

In equation (3), the quantity “e₃₁(x)-e₃₃(x)×(C₁₃(x)/C₃₃(x))” is negative for the entire composition range. Consequently, the piezoelectric polarization P_{PE}(X) will be negative for the barrier layer of AlₓGa₁₋ₓN stressed in tension.

The polarization discontinuity at the AlₓGa₁₋ₓN/GaN interface 6 between the barrier layer of AlₓGa₁₋ₓN and the channel layer of GaN generates a positive charge distribution at the AlₓGa₁₋ₓN/GaN interface 6, for which the density is written as follows:
σ=P(AlGaN)−P(GaN)
σ=P_{SP}(AlGaN−P_{PE}(AlGaN)−P_{SP}(GaN) (4)

Equations (1), (3) and (4) are used to calculate the charge density σ/e (where e=1.6×10⁻¹⁹ C) for stressed structures.

If the aluminum content in the AlₓGa₁₋ₓN barrier layer is between 5% and 30%, then the charge density induced by the polarization is between 2×10¹² cm⁻² and 2×10¹³ cm⁻². In order to compensate for this high positive charge, a two-dimensional electron gas will be formed at the AlₓGa₁₋ₓN/GaN interface 6. Therefore, there is an additional contribution to that induced by the band structure.

The simple model by Ambacher et al described above demonstrates dependence between the charge density induced by polarization and the concentration of aluminum in the AlₓGa₁₋ₓN barrier layer. Thus, the charge carrier mobility and charge density properties of transistor structures obtained starting from a Type III-Type N-based semiconductor material depend on parameters such as the chemical roughness at the AlGaN/GaN interface and the aluminum concentration in the AlGaN barrier. These parameters are related to methods of producing the semiconductor structure based on Type III-Type N, and generate problems with the reliability of transistor structures made on the semiconductor material.

FIG. 6a is a sectional view illustrating a semiconducting material of the prior art based on III-N. This material comprises a classical barrier layer 40 on a channel layer 41. A drawback of the semi-conducting material of the prior art is the non-homogeneous distribution of Ga and Al atoms in the barrier layer 40. This is due in particular to the difference in behaviour of Ga and Al in terms of diffusion capacity, and to segregation effects which follow this difference in behaviour.

This non homogeneous distribution of Ga and Al atoms in the barrier layer 40 induces non-homogeneity of the piezoelectric field 38 at the interface 39 between the channel layer 41 and the barrier layer 40. Indeed, the direction and the intensity of the piezoelectric field locally depend on the distribution of Ga and Al atoms in the barrier layer 40. The non-homogeneity of the piezoelectric field induces fluctuations in the electronic density at this interface 39. As a consequence, the power output by a transistor structure made on the semi-conducting material comprising this AlGaN barrier layer will be distributed non-homogeneously. Moreover, the non-homogeneous distribution of Ga and Al atoms induces non-homogeneity of the electron distribution (particularly in the channel layer).

PCT publication WO02/093650 describes a process for making a semi-conducting structure comprising a barrier layer including an alternation of layers of GaN and AlN, each layer of AlN and GaN being in the range of 5 to 20 Angstroms thick. As will be apparent when reading the description of the present invention, an embodiment of WO02/093650 thus shares with the present invention alternating layers of binary materials for making a larger layer of material. The process disclosed in WO02/093650 allows increasing the electron mobility within the structure, but it does not address the issue of increasing the homogeneity of the electron distribution (particularly in the channel layer). And in this respect the process disclosed by WO02/093650 does not provide a solution for increasing the homogeneity of the electron distribution in the layers of the structure. Moreover, WO02/093650 does not allow increasing homogeneity of the piezoelectric field at the interface between the barrier layer and the channel layer and thus does not allow limiting the fluctuations in the electronic density at this interface.

It can also be noted that other processes disclose alternating elementary layers of different materials for making a larger layer. And some of these known processes even disclose selecting very thin elementary layers. Reference may be made in this respect to U.S. Pat. No. 6,100,542. The known process of that patent does not address layers of materials based on nitrides, but materials based on arsenide. It will be appreciated that this known process does not suggest how to address the issue of homogeneity or how to provide specific means to treat this issue.

It thus appears that the existing processes for making structures with layers based on nitrides are associated to some limitations and the present invention now addresses these limitations. And more precisely, it is necessary to increase the homogeneity of the electron distribution, particularly in the channel layer, to overcome the prior art limitations. Another desirable solution is to increase the homogeneity of the piezoelectric field at the interface between the barrier layer and the channel layer and thus to homogenise the electronic density at this interface. These solutions would improve the electronic properties of semi-conducting materials based on III-N. Such solutions and methods of making such semi-conducting materials are goals of the present invention.

Prior art electronic circuits based on Gallium nitride (GaN) used in high frequency and high power applications also suffer from reliability problems. One reason for such problems is that non-homogenous electronic density distributions exist in these structures that originate from alloy disorders at the atomic and micrometric scale. Therefore, a need exists for improving the reliability of transistor structures based Type III-Type N semiconductor materials, particularly by improving methods of producing the semiconductor structures utilizing Type III-Type N materials.

### SUMMARY OF THE INVENTION

The present invention relates to a piezoelectric structure comprising a semi-conducting substrate based on elements in Groups III and V of the periodic table, with the Group V element preferably being nitrogen. The substrate typically includes a support, a channel layer on the support and a barrier layer on the channel layer, wherein the barrier layer is composed of, on an atomic scale, alternating layers of first and second Group III-V binary semi-conducting alloys. This substrate is useful for HEMT or HEMT-type transistors and related devices that require high quality piezoelectric properties.

Advantageously, the channel layer is composed of, on an atomic scale, alternating layers of third and fourth Group III-V binary semi-conducting alloys. Also, the semi-conducting substrate may include a buffer layer between the support and the channel layer, wherein the buffer layer is composed of, on an atomic scale, alternating layers of fifth and sixth Group III-V binary semi-conducting alloys. Preferably, the number of monolayers in each set of alternating layers of the barrier layer, the channel layer or the buffer layer is between 1 and 20. The first, second, third, fourth, fifth and sixth binary alloys may be the same or different and preferably may be AlN, GaN, BN, or InN as nitrogen is preferred as the Group V element.

In one embodiment, the number of monolayers in each set of alternating layers of the barrier layer, the channel layer or the buffer layer varies between a first value on a back face of the barrier layer or of the channel layer or of the buffer layer, and a second value on a front face of the barrier layer, the channel layer or the buffer layer, the back face(s) being closer to the support than the front face. These first and second values can vary between 1 and 20, optionally with the first value being greater than the second value.

The barrier layer may also include a layer of a Group III-V semi-conducting ternary alloy. In this embodiment, the alternating layers of first and second Group III-V semi-conducting binary alloys can be located between the support and the layer of Group III-V semi-conducting ternary alloy. Alternatively, the barrier layer can include a plurality of layers of Group III-V semi-conducting ternary alloy, with each layer of the Group III-V semi-conducting ternary alloy being located between a layer of the first binary alloy and a layer of the second binary alloy. Preferably, the barrier layer comprises a layer of the Group III-V semi-conducting ternary alloy on the layers of the first and second Group III-V semi-conducting binary alloys. The barrier layer typically has a thickness of between 2 nm and 500 nm.

The channel layer may also comprise a plurality of layers of Group III-V semi-conducting ternary alloy, with each layer of the Group III-V semi-conducting ternary alloy being located between a layer of the third binary alloy and a layer of the fourth binary alloy. Each layer of the ternary alloy, whether present I the barrier layer or the channel layer, includes between 1 and 5 atomic monolayers. The channel layer may be made of a layer of ternary alloy of AlGaN, or InGaN, or AlBN, or InBN, or InAlN, or of a layer of binary alloy of GaN, or AlN, or BN, or InN again as nitrogen is preferred as the Group V element.

The semi-conducting substrate may include a buffer layer between the support and the channel layer, with the buffer layer being made of a layer of binary alloy of GaN, or AlN, or BN, or InN, or of a layer of ternary alloy of AlGaN, or InGaN, or AlBN, or InBN, or InAlN. Also, the support is typically made of Si, SiC, AlN, Sapphire, or GaN.

The invention also relates to a method for preparation of a semi-conducting substrate comprising a support, a channel layer on the support and a barrier layer on the channel layer, which comprises creating the barrier layer by depositing at least one atomic monolayer of a first binary alloy; depositing at least one atomic monolayer of a second binary alloy; and repeating the depositing as necessary until a desired thickness is obtained.

The method can further include creating at least one layer of ternary alloy in or on the barrier layer. The ternary alloy can be created by depositing a layer of a ternary alloy on the barrier layer or by thermally treating the atomic monolayers of the first and second binary alloys to form the ternary layer. The thermally treating can be carried out after at least some depositing of the second binary alloy under different conditions. The thermally treating can be conducted at a surface temperature between 0° C. and 300° C. above to the temperatures where the first and second binary alloy monolayers are created; under vacuum or ultra-high vacuum between 10⁻⁸ Torr and 10⁻¹ Torr; under a gas mixture flow comprising ammonia, nitrogen or hydrogen at a pressure comprised between 10⁻⁸ Torr and 1 kBar; or in the presence of an ammonia, nitrogen or hydrogen plasma. Also, the thermally treating can be conducted after creating the initial barrier layer.

The channel layer can be created by depositing a binary alloy of GaN, or AlN, or BN, or InN, or by depositing a ternary alloy of AlGaN, or InGaN, or AlBN, or InBN, or InAlN. Alternatively, the channel layer can be created by depositing an atomic monolayer of a third binary alloy; depositing an atomic monolayer of a fourth binary alloy; and repeating the depositing as necessary until a desired thickness is obtained. The channel layer also can be created by thermally treating the third and fourth binary alloy monolayers before depositing the fourth binary alloy, either at a surface temperature between 0° C. and 300° C. above to the temperature of creation of monolayers of third and fourth binary alloys; under vacuum or ultra-high vacuum between 10⁻⁸ Torr and 10⁻¹ Torr; under a gas mixture flow comprising ammonia, nitrogen or hydrogen at a pressure comprised between 10⁻⁸ Torr and 1 kBar; or in the presence of an ammonia, nitrogen or hydrogen plasma.

If desired, a buffer layer can be created by depositing a binary alloy of GaN, or AlN, or BN, or InN

### BRIEF DESCRIPTION OF THE DRAWING FIGURES

Other aspects, purposes and advantages of the invention will become clear after reading the following detailed description with reference to the attached drawings, in which:

FIG. 1 is a simplified cross-sectional view of a conventional semiconductor structure based on a nitride of a Type III element on which an HEMT type transistor was made;

FIG. 2 is a simplified cross-sectional view of a conventional semiconductor structure based on a nitride of a Type III element;

FIG. 3 is a simplified sectional view of an interface between a binary material and a ternary material according to the prior art;

FIG. 4 is a simplified sectional view of a ternary material of the prior art;

FIG. 5a is a simplified sectional view of a ternary material illustrating the alloy order in the [001] symmetric planes;

FIG. 5b is a simplified sectional view of a ternary material of the prior art illustrating the alloy order in the [1-101] asymmetric planes;

FIG. 6a is a sectional view of binary and ternary material layers in the case of a ternary material of the prior art;

FIG. 6b is a sectional view of binary and ternary material layers in the case of an ideal ternary material;

FIG. 6c is a sectional view of binary and ternary materials obtained using the method according to the invention;

FIGS. 7a to 7g show sectional views of different embodiments according to the invention;

FIGS. 8a and 8b show sectional views of examples of pseudo-alloy ternary material obtained by methods according to the invention;

FIG. 9 shows an example of semi-conducting material according to the invention;

FIG. 10 shows an example of barrier layer according to the invention;

FIG. 11 is a diagram illustrating the thickness of the barrier layer in function of the Al concentration for different embodiments according to the present invention;

FIGS. 12A to 12D illustrate the roughness of two embodiments of semi-conducting materials according to the present invention;

FIGS. 12E to 12I illustrate different surface morphologies of AlGaN/GaN HEMT structure according to the present invention for different Aluminium concentrations in the AlGaN barrier (25 nm thick);

FIG. 13 shows another example of semi-conducting material according to the invention; and

FIGS. 14 shows two additional embodiments according to the present invention.

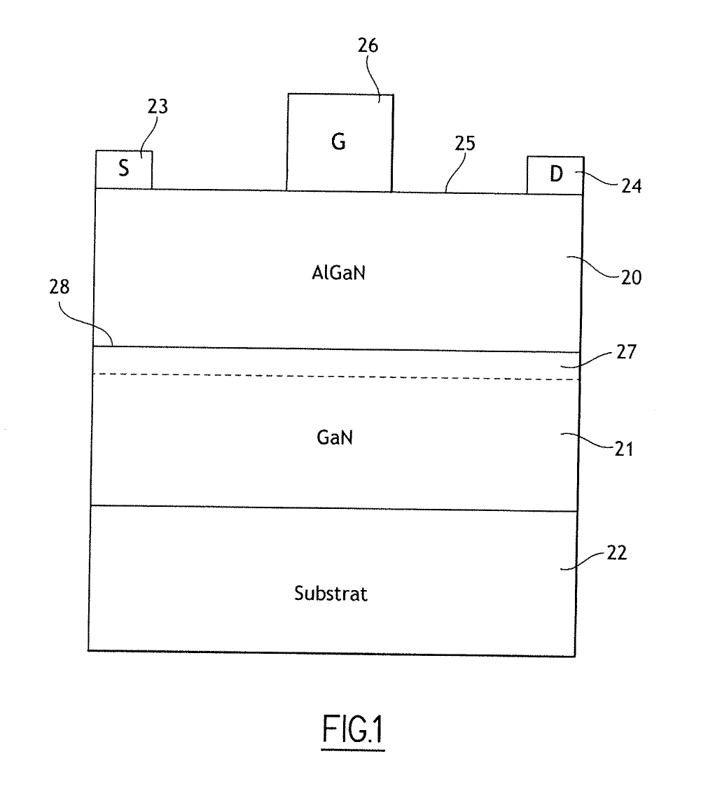

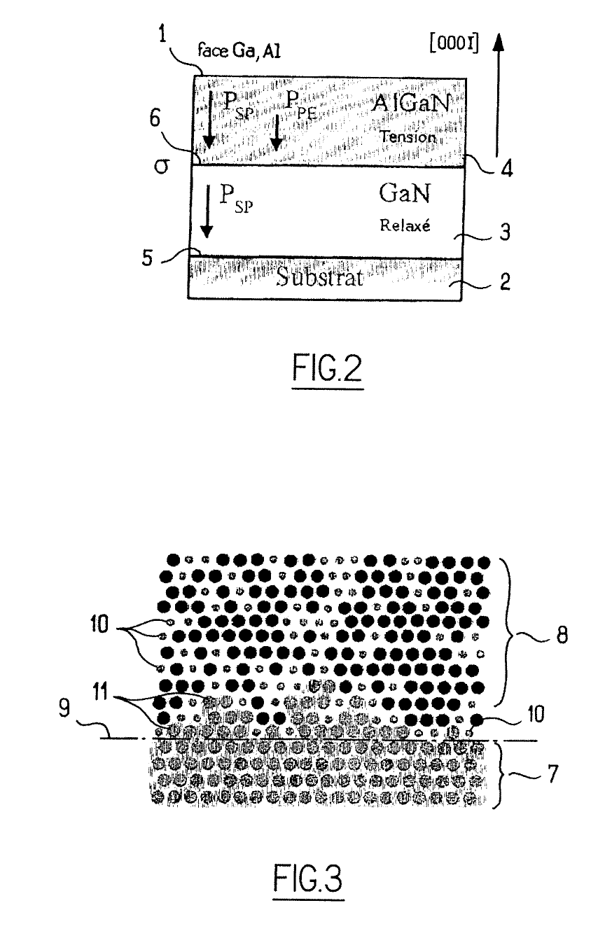

### DETAILED DESCRIPTION OF THE PREFERRED EMBODIMENTS

The present invention provides methods for manufacturing semiconductor structures based on nitrides of Type III elements (Al, Ga, In)/N perfectly ordered along a preferred crystalline axis. To obtain this result, the ternary alloy barrier layer is replaced by a barrier layer that includes alternating binary alloy barrier layers.

The perfectly ordered structure along a preferred crystalline axis is obtained with specific deposit conditions to control the layer formation on an atomic scale and to avoid fluctuations in the composition of the layer. It includes a MBE deposit with a preferred growth rate between 10 and 50 Å/min, a preferred temperature of between 700 to 800° C. and a pressure that is less than 5×10−4 Torr.

The lack of fluctuation in the composition of these structures improves electron transport properties and makes the distribution more uniform.

The invention relates to a semiconductor structure or substrate based on elements in columns III and V in the periodic table for use, for example, to fabricate HEMT type transistor structures. Such semiconductor structures include a support, a channel layer on the support and a barrier layer on the channel layer, wherein the barrier layer is composed of alternating binary semiconductor alloy layers.

A semiconductor structure that includes a barrier layer composed of alternating binary alloy layers has the following advantages. It has zero alloy disorder at the atomic level, zero alloy non-homogeneities at the nanometric level and at the microscopic level, a perfect alloy order according to a privileged crystalline axis, a maximum piezoelectric field along a preferred crystalline axis, an optimum electron piezoelectric injection, a very uniform electronic density per unit surface area, reduced electronic diffusion at interfaces and in the barrier layer due to the zero alloy disorder, and improved structure reliability due to the absence of any alloy non-homogeneities.

It should be understood that when a layer A is mentioned as being “on” a layer B, it may be directly on layer B, or it may be located above layer B and separated from layer B by one or several intermediate layers. It should also be understood that when a layer A is said to be “on” a layer B, it may cover the entire surface or just a portion of layer B.

In several beneficial, non-limitative aspects, the semiconductor structure includes one more of the following features. Each binary alloy layer is composed of atomic monolayers, and the number of atomic monolayers in each binary alloy layer forming the barrier layer may be between about 1 and about 40, and preferably between about 1 and about 20, and more preferably between about 2 and about 10. The number of atomic monolayers in each binary alloy layer that forms the barrier layer may vary between a first value on a back face of the barrier layer and a second value on a front face of the barrier layer, wherein the back face is closer to the support than the front face. The first and second values are between about 1 and about 40, preferably between about 1 and about 20, and more preferably between about 2 and about 10. The thickness of the barrier layer may be between about 2 nm and about 500 nm. Also, the barrier layers may be perfectly ordered along a preferred crystalline axis.

The semiconductor structure may also include a buffer layer between the support and the channel layer, and the buffer layer is a material chosen from among AlGaN and GaN. In a preferred embodiment, the buffer layer is a ternary pseudo-alloy of AlGaN, the pseudo alloy being composed of alternating binary alloy layers of AlN and GaN. The barrier layer may also be a ternary pseudo-alloy of AlGaN, or InGaN, or AlBN, or InBN, or InAlN. The binary alloy layers that form the barrier layer may be made from materials chosen from among AlN, GaN, BN, and InN. In a preferred embodiment, the channel layer is made of a material chosen from among AlN, GaN, BN, and InN. Moreover, the channel layer is a ternary pseudo-alloy of AlGaN, or InGaN, or AlBN, or InBN, or InAl. The ternary pseudo alloy is preferably made of alternating layers of binary alloys chosen from among AlN, GaN, BN, or InN. Further, the support is preferably made of a material chosen from among silicon, SiC, AlN, sapphire and GaN. The thickness of each layer of binary alloy of the buffer layer can vary between a first value on a back face of the buffer layer and a second value on a front face of the buffer layer, wherein the back face is closer to the support than the front face. Again, the binary alloys can be perfectly ordered along a preferred crystalline axis.

The invention also relates to a method for fabricating a semiconductor substrate that includes a support, a channel layer on the support and a barrier layer on the channel layer. The barrier layer is composed of alternating layers of binary alloys. The technique includes growing the channel layer on the support, creating the barrier layer by depositing at least one atomic monolayer of a first binary alloy, depositing at least one atomic monolayer of a second binary alloy, and repeating these steps until a required thickness is obtained for the barrier layer.

Preferred but non-limiting aspects of the method according to the invention include that the channel layer is grown over the entire surface of the support, and atomic monolayers of the first and second binary alloys are deposited over the entire surface of the channel layer. The method may also include depositing a buffer layer of GaN or AlGaN. A buffer layer of AlGaN may also be created, and its formation may include depositing at least one first binary alloy atomic monolayer of GaN, depositing at least one second binary alloy atomic monolayer of AlN, and repeating these steps, if necessary, until a required thickness is obtained for the buffer layer.

The method may include fabricating the channel layer of AlN, or GaN, or BN or InN or InGaN on a support of silicon, or SiC, or AlN, or sapphire, or GaN. The technique may also include fabricating the barrier layer of AlGaN or InGaN, or AlBN, or InBN, or InAlN by depositing atomic monolayers of the first binary alloy and the second binary alloy, the first and second binary alloys being chosen from among AlN, InN, GaN, BN. In a preferred embodiment, the AlGaN barrier layer is fabricated by depositing at least one atomic monolayer of the first binary alloy of GaN, depositing at least one atomic monolayer of the second binary alloy of AlN, and repeating these depositing steps if necessary, until the required thickness is obtained for the AlGaN barrier layer.

One purpose of the present invention is to provide a method capable of producing a semiconductor structure based on an improved Type III-Type N material. In other words, the material provides for improved transistor structure properties in terms of mobility of carriers, charge density and reliability of the final structure.

The present invention allows an increase electron mobility in the gaz of electrons of μₙ=2090 cm²/V·s for a electron density in the of nₛ=7·10¹² at·cm⁻².

The applicants studied the material parameters that limit the mobility, charge density and structure reliability properties, and these material parameters include the roughness value at interfaces, alloy fluctuations and alloy order.

Type 1 Non-Homogeneities: Roughness at Interfaces

The roughness observed at interfaces may be physical or chemical. The mobility of electrons in the GaN channel layer of a semiconductor structure based on Type III-Type N materials is particularly sensitive to chemical roughness. The chemical roughness depends on the composition of the structure, and occurs as soon as a ternary material (for example AlGaN, InGaN, InAlN, AlBN, GaBN) is introduced into the structure.

FIG. 3 shows an interface 9 between a GaN channel layer 7 and an Al_{0.3}Ga_{0.7}N barrier layer 8. The GaN channel layer 7 is located below the interface 9, and the Al_{0.3}Ga_{0.7}N barrier layer 8 is located above the interface 9. As shown, some atoms 111 of the GaN channel layer 7 are above the interface 9. Therefore, a roughness phenomenon occurs at the Al_{0.3}Ga_{0.7}N/GaN interface 9.

Type 2 Non-Homogeneities: Alloy Fluctuations

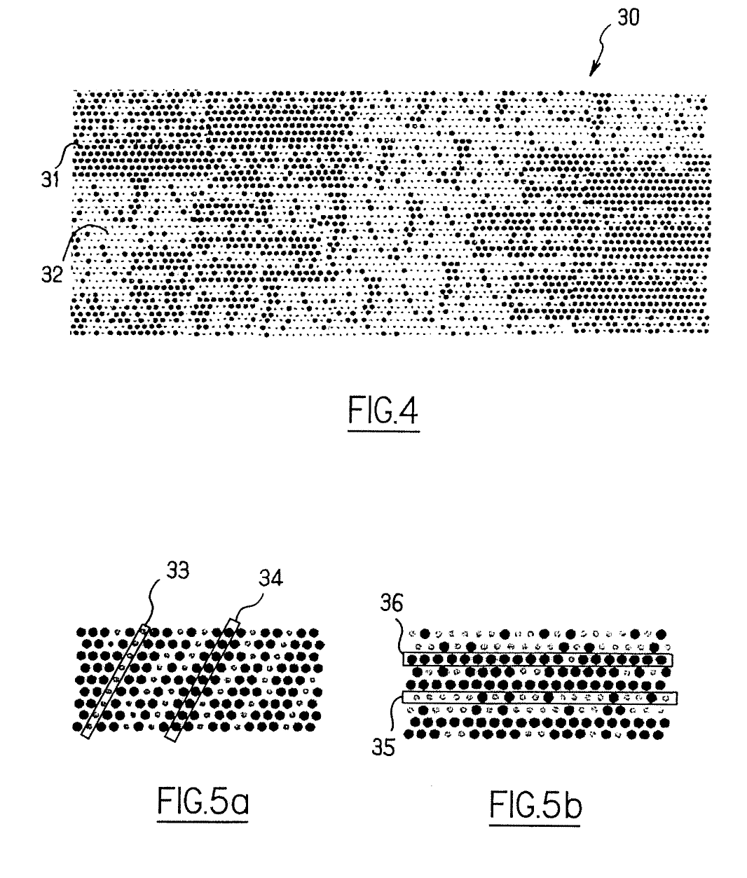

FIG. 4 shows a non-homogenous distribution in a barrier layer 30 made of AlGaN, of a Type III-Type N based semiconductor material. “gallium rich” areas 31 and “aluminum rich” areas 32 are frequently created due to the surface diffusion rates of gallium and aluminum precursors during fabrication of the semiconductor structure, because aggregates form and develop. This type of defect is know as an alloy fluctuation.

Alloy fluctuations reduce the mobility of electrons and play an important role in the reliability of transistors made from Type III-Type N semiconductor materials. In particular, these alloy fluctuations degrade the piezoelectric electron injection so that it becomes non-homogenous, which results in a non-homogenous charge density in the channel of the transistors produced. Alloy fluctuations are a main source of failure of power transistors, since the current density in such transistors is not homogenous.

Type 3 Non-Homogeneities: The Alloy Order

The alloy order is a defect similar to that of an alloy fluctuation, but it is at the atomic level. The alloy order is due to growth parameters and is the result of a partially ordered distribution of the constituent atomic elements of a ternary material. For example, in the case of an AlGaN barrier layer, “aluminum rich” atomic planes can be observed alternating with “aluminum depleted” atomic planes. The average composition of the alloy corresponds to the target, with ordered fluctuations at the atomic level.

The alloy order may appear in several crystalline directions. This alloy order may be induced by growth parameters and stress. In all cases, it is a “spontaneous” order that is not deliberately introduced into the semiconductor structure. Consequently, it is uncontrolled and non-homogenous.

FIG. 5a shows the alloy order in the [1-101] asymmetric planes of an AlGaN barrier layer, which means in planes perpendicular to the [0001] growth axis. “aluminum rich” atomic planes 33 and “aluminum depleted” atomic planes 34 are shown. The alloy order is formed in the [1-101] asymmetric planes when epitaxy production systems are used in which the supports are placed on a rotating plate. This result occurs because aluminum and gallium have a faster depletion rate in the gas or molecular mix used in the method for manufacturing the semiconductor structure (uncontrolled parasite reactions of precursors). Thus, the support will be exposed alternately to an “aluminum rich” gas or molecular mix, then to an “aluminum depleted” gas or molecular mix.

FIG. 5b shows the alloy order in the [001] symmetric planes of an AlGaN barrier layer. “Aluminum rich” atomic planes 35 and “aluminum depleted” atomic planes 36 are shown. The alloy order in the [001] symmetry planes is due to non-homogenous stress distributions and differences in the stability of the crystalline surfaces.

Effects of Type 1, 2 and 3 Non-Homogeneities

The three defect types explained above (roughness at interfaces, alloy fluctuations, and alloy order) occur when conventional methods are used to fabricate the semiconductor structure, and they generate reliability problems for transistors made on the semiconductor structure. As already demonstrated using the Ambacher et al. model, the charge density induced by polarization depends on the aluminum concentration in the AlGaN barrier layer. A local variation +/−2% of the aluminum content can make the electronic density fluctuate by 2×10¹² cm⁻² or more.

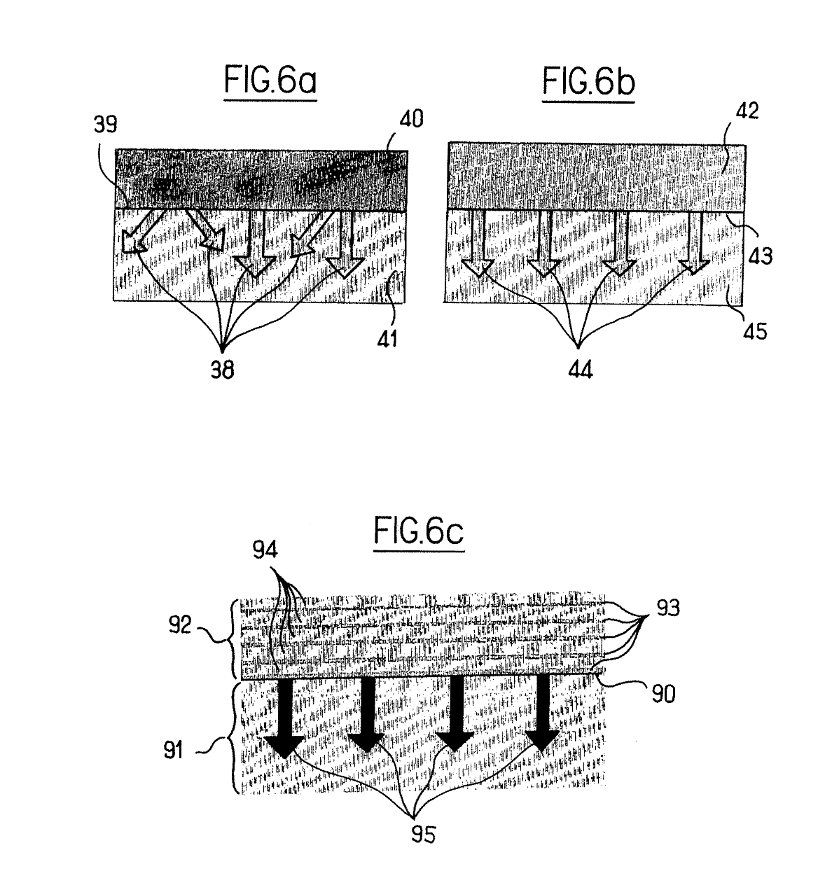

FIG. 6a illustrates use of a standard AlGaN barrier layer 40, wherein the direction and intensity of the piezoelectric field 38 at the interface 39 between the barrier layer 40 and the channel layer 41 locally depends on the distribution of Ga and Al atoms in the barrier layer 40. The direction and intensity of the piezoelectric field will induce fluctuations in the electronic density at this interface 39. Similarly, the power output of a transistor made on the semiconductor structure that includes the standard AlGaN barrier layer will be non-homogenously distributed.

FIG. 6b illustrates the average value of the piezoelectric field 44 for an ideal barrier layer 42. The average value for such an ideal barrier layer is equal to the local value of the field at any point on the interface 43 between the barrier layer 42 and the channel layer 45. Therefore, the electronic density is homogenous at the interface 43.

It is thus important to have a semiconductor structure with a correctly ordered barrier layer in order to eliminate the three types of non-homogeneities mentioned above, and thus to obtain better transistor structure properties. In order to obtain a semiconductor structure with a correctly ordered barrier layer, the applicants replaced the conventional barrier layer made of a ternary alloy (with Type III-Type N-based semiconductor materials) with a barrier layer made of a ternary pseudo-alloy. For the purposes of this disclosure, a ternary “pseudo-alloy” is an alloy composed of alternating atomic monolayers of binary alloys.

As noted above, the perfectly ordered structure along a preferred crystalline axis is again obtained with specific deposit conditions to control the layer formation on an atomic scale and to avoid fluctuations in the composition of the layer. It includes a MBE deposit with a preferred growth rate between 10 and 50 Å/min, a preferred temperature between 700-800° C. and a pressure that is less than 5×10⁻⁴ Torr.

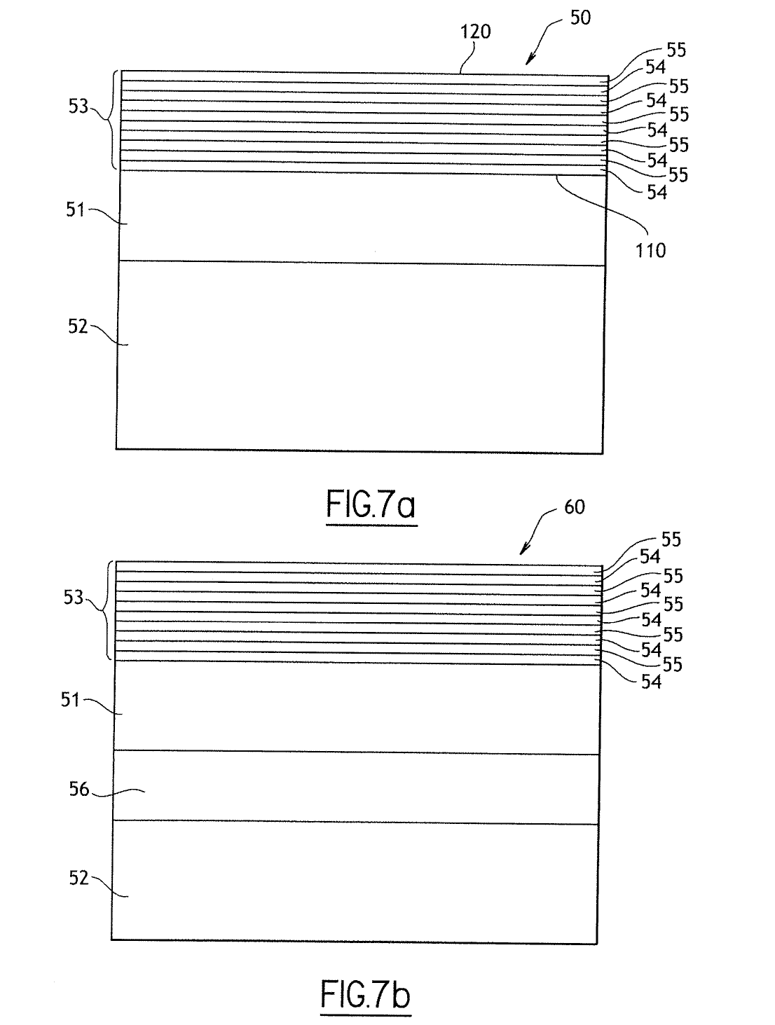

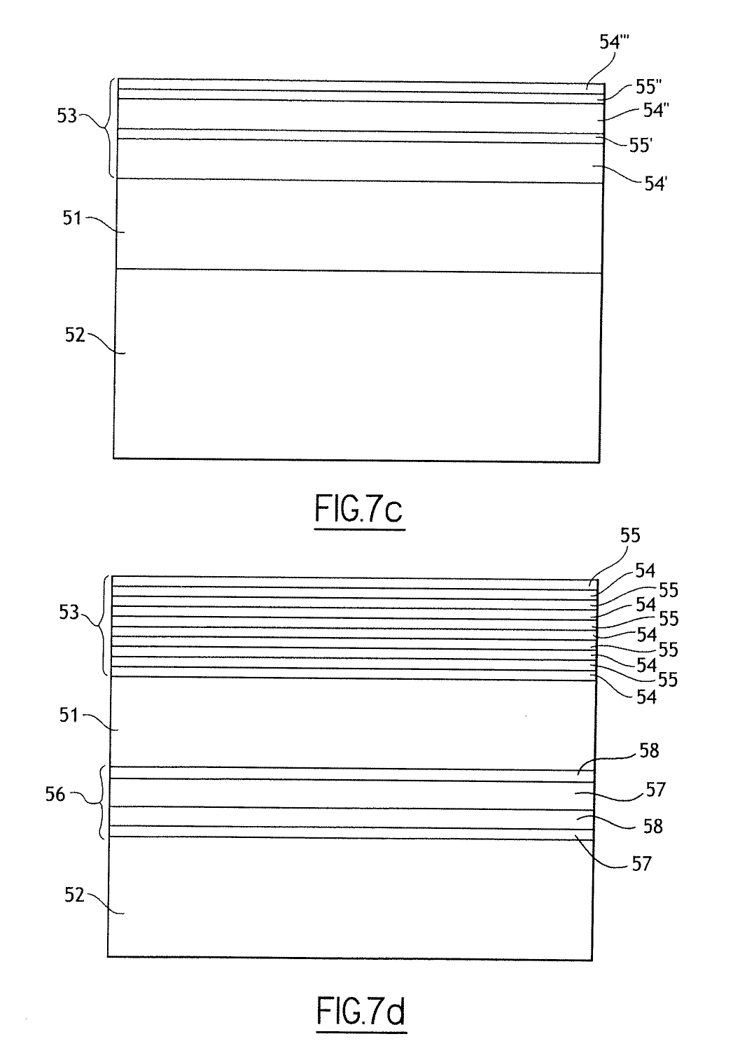

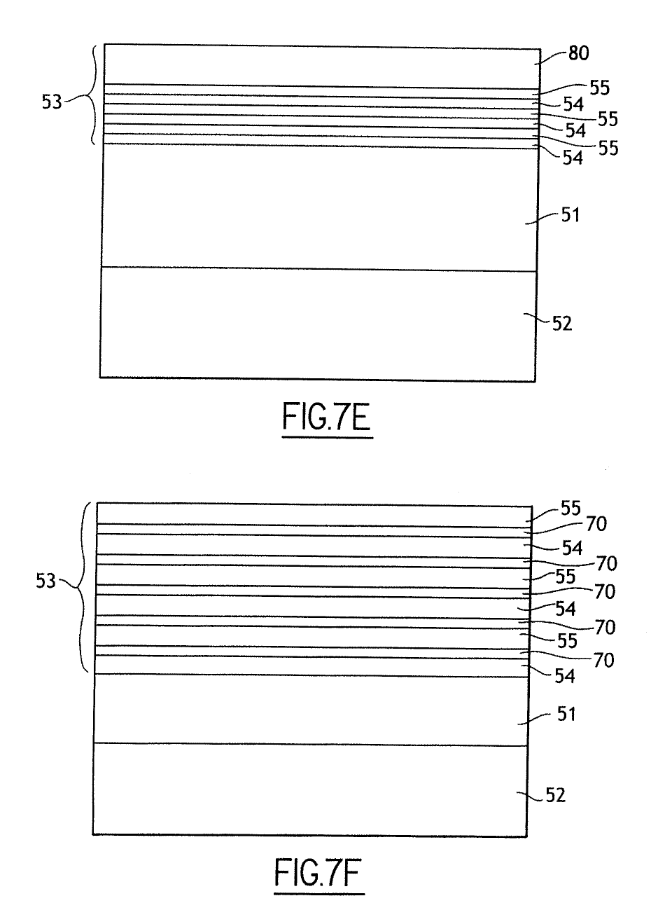

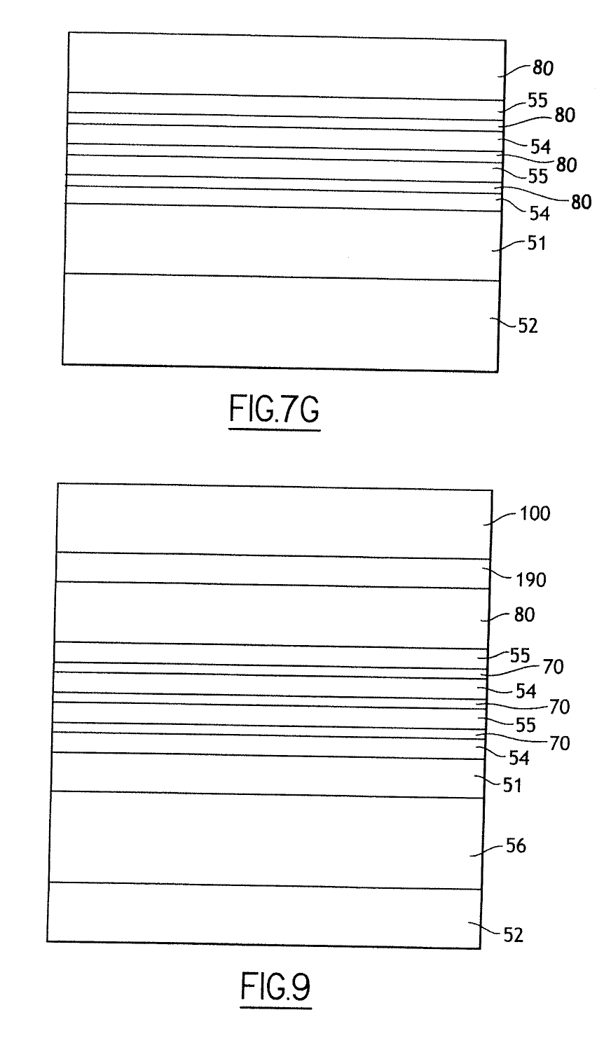

FIG. 7a illustrates a semiconductor structure 50 according to a first embodiment of the invention. This semiconductor structure 50 comprises a channel layer 51 on a support 52, and a barrier layer 53 made of a ternary pseudo-alloy on the channel layer 51. The support 52 is made of SiC. However, the support could be made of other materials such as Silicon, AlN, sapphire or GaN. The channel layer 51 is a binary alloy of GaN. However, another material could have been chosen for the channel layer 51, such as AlN, BN (boron nitride) or InN (indium nitride). The channel layer 51 is deposited on the support by a method known to those skilled in the art such as Molecular Beam Epitaxy (MBE) or Metal-Organic Chemical Vapor Deposition (MOVD) method.

The barrier layer 53 is a ternary pseudo-alloy of AlGaN. The barrier layer 53 comprises binary alloy layers of GaN 54 and binary alloy layers of AlN 55. The GaN and AlN layers are supplied in an alternating fashion. Each binary alloy layer made of GaN 54 (or AlN 55) is composed of one or several atomic monolayers of GaN (or AlN). Those atomic monolayers of GaN and AlN are individually fitted in the semi-conducting material in order to obtain a barrier layer as homogeneous as possible.

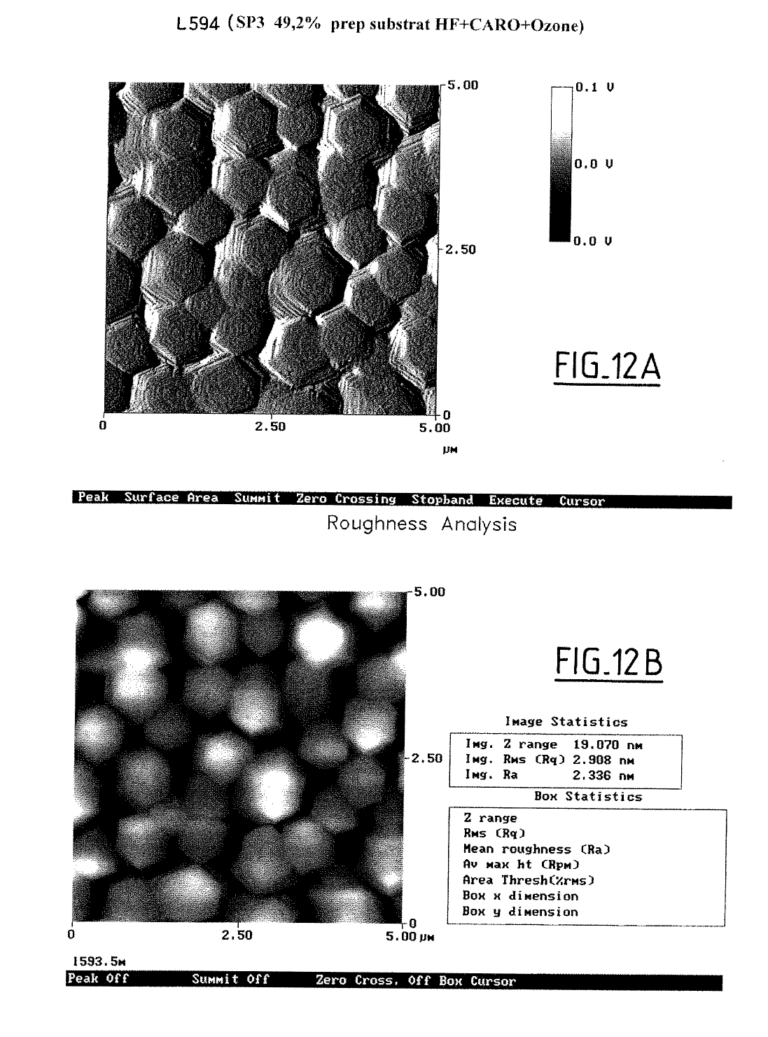

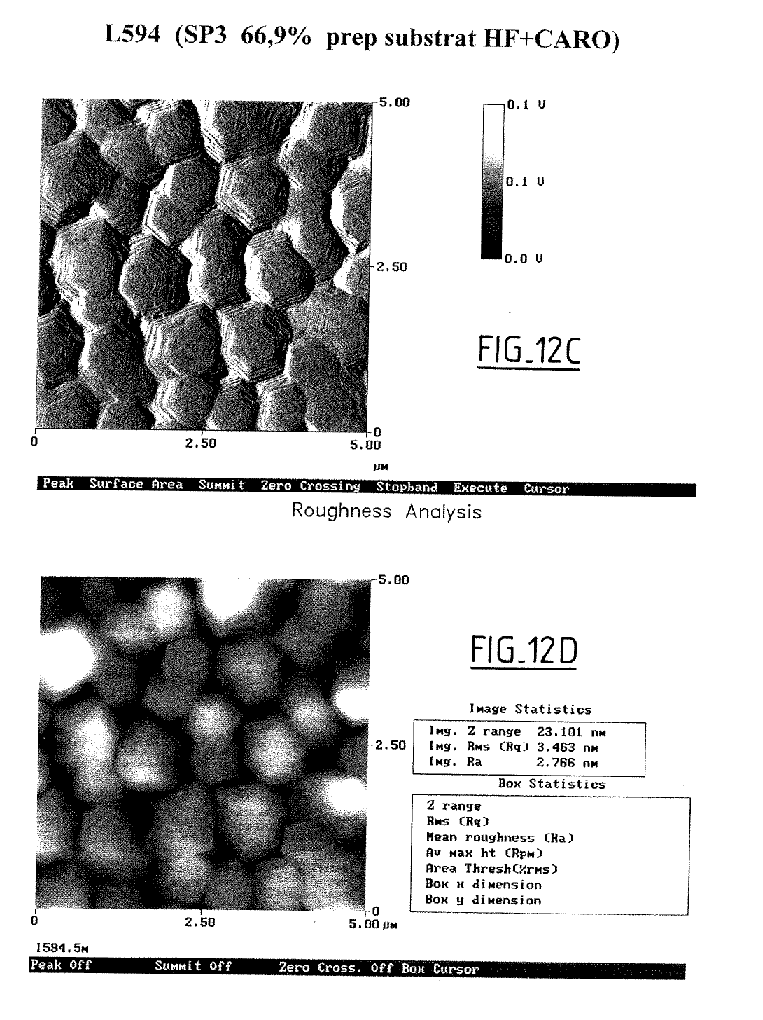

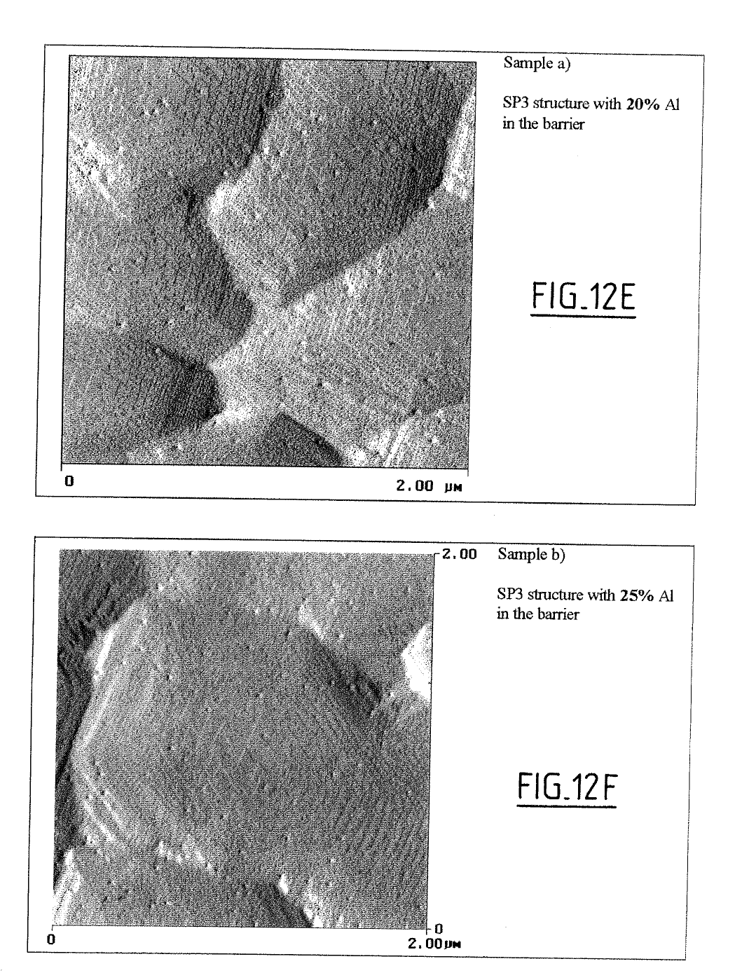

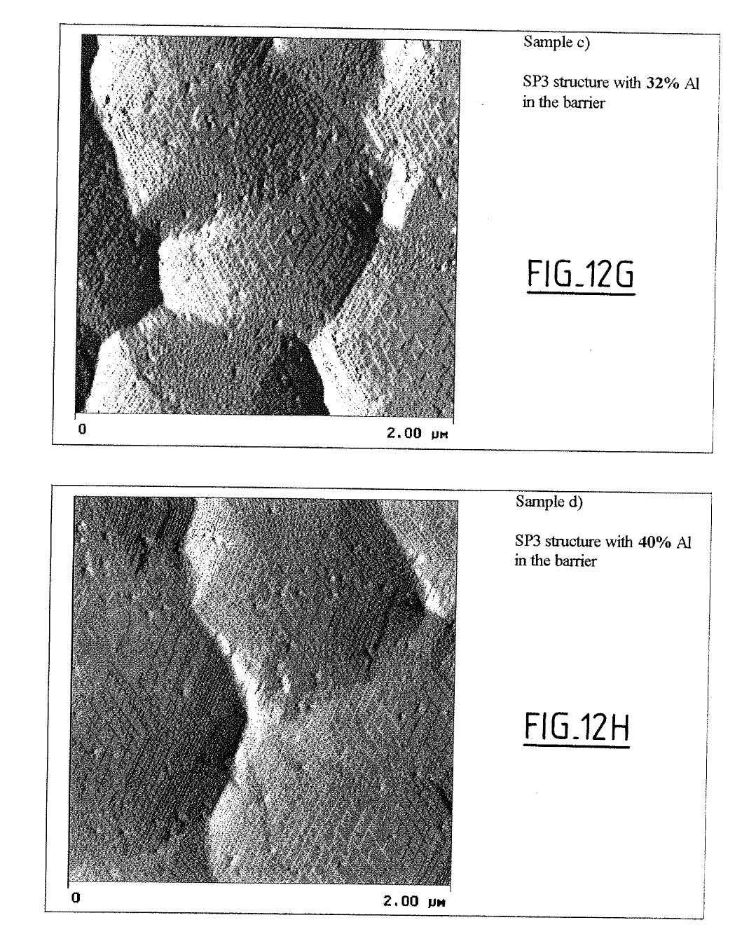

FIG. 12A to 12D illustrates the roughness of the semi-conducting materials according to the present invention for different concentrations of Ga and Al in the barrier layer. The number of atomic monolayers (denoted n_{GaN}) per layer of the first binary alloy made of GaN 54 can vary between 1 and 40, and preferably between 1 and 20, and even more preferably between 2 and 10. Similarly, the number of atomic monolayers (denoted n_{AlN}) per layer of the second binary alloy made of AlN 55 can vary between 1 and 40, and preferably between 1 and 20, and even more preferably between 2 and 10.

It shall be appreciated that existing processes such as the one disclosed in U.S. Pat. No. 6,100,542 indeed involve making layers with an alternation of very thin elementary layers—and in this respect these processes present some similarities with the alternation of monolayers mentioned above. However, U.S. Pat. No. 6,100,542 addresses materials based on arsenides and not nitrides, and its alternation aims at maximizing the doping of the larger layer thus constituted with the elementary layers. Thus, U.S. Pat. No. 6,100,542 does not address the issue of homogeneity of the distribution of electrons. Indeed, that patent concerns non-piezoelectric structures. The skilled artisan knows that alloy disorders in the layers of a non piezoelectric arsenide structure do not interfere with the homogeneity of the distribution of electrons. Hence, materials based on arsenides which comprise an alternation of elementary layers do not address the issue of homogeneity of the distribution of electrons.

It shall also be appreciated that existing processes such as the one disclosed in WO02/093650 indeed involve making layers with an alternation of “monolayers” as mentioned at page 7 third paragraph of WO02/093650. However, these “monolayers” are far from the definition of monolayer in the sense of the present invention. Indeed, the “monolayers” as described in WO02/093650 are in the range of 5 to 20 angstrom thick (see WO02/093650 page 7 third paragraph), which is very thick with respect to the monolayers of the present invention which are atomic monolayers.

WO02/093650 does address the problem of increasing the electron mobility within the structure, but that publication does not address the issue of increasing the homogeneity of the electron distribution (particularly in the channel layer). Indeed WO02/093650 does not suggest monolayers as defined in the present invention (the “monolayer” as defined in WO02/093650 being very thicker as the one of the present invention, which is about 1 to 20 angstroms).

In the present invention, the production method known to those skilled in the art such as liquid phase epitaxy, or vapour phase epitaxy or molecular beam epitaxy is used to grow the barrier layer 53 on the channel layer of GaN. The barrier layer 53 is created starting by depositing a layer of the first binary alloy of GaN 54 in which the number of atomic monolayers n_{GaN} is between 1 and 40, preferably between 1 and 20 and even more preferably between 2 and 10, and the next step is to deposit a layer of the second binary alloy of AlN in which the number of atomic monolayers n_{AlN} is between 1 and 40, preferably between 1 and 20 and even more preferably between 2 and 10. The next step is to deposit layers of the first binary alloy of GaN and layers of the second binary alloy of AlN until the required thickness of the barrier layer 53 is obtained, varying between 2 and 500 nm.

In the embodiment shown in FIG. 7a, the numbers of atomic monolayers n_{GaN} and n_{AlN} are equal. However, the numbers of atomic monolayers n_{GaN} and n_{AlN} could be different.

Since the barrier layer 53 is composed of alternations of layers of GaN and AlN, the gas or molecular precursors of Gallium and of Aluminium (or Gallium and Aluminium) are not mixed during the production method and there is no mix depletion phenomenon.

Thus, alloy fluctuations are limited both at the nanometric and micrometric scales (type 1 non-homogeneities), and at the atomic scale (type 2 and 3 non-homogeneities). Therefore the structure of the barrier layer 53 is perfectly ordered along the [0001] growth axis.

As illustrated in FIG. 6c, this perfectly ordered structure has the effect of limiting the chemical roughness and consequently limiting the diffusion of electrons at the interface 90 between the channel layer 91 and the barrier layer 92 (this barrier layer being composed of an alternation of AlN layers 93 and GaN layers 94). It also has the effect of optimising the distribution of the piezoelectric field for which the average value is equal to the local value of the piezoelectric field 95 at all points on the interface 90.

Therefore, the injection of electrons by this field is optimised. Moreover, the distribution of electrons injected into the two-dimensional gas (2 DEG) is homogenous since the induced piezoelectric field is homogenous. Consequently, this structure provides a means of optimising the mobility and the surface density of electrons located in the two-dimensional gas (2 DEG).

As above, the present invention allows an increase electron mobility in the gaz of electrons of μₙ=2090 cm²/V·s for a electron density in the of nₛ=7·10¹² at·cm⁻².

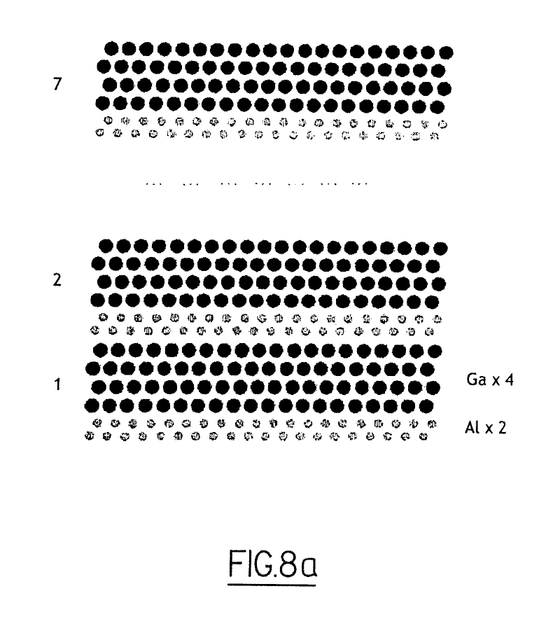

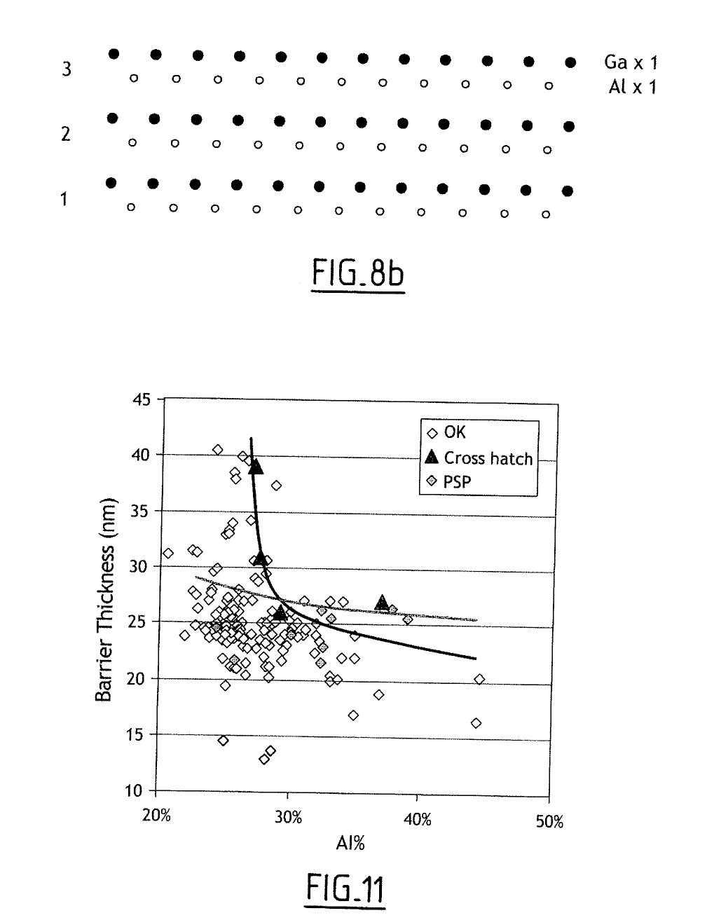

FIG. 8a illustrates an example embodiment of a barrier layer according to this invention. In this example, a 20.5 nm thick barrier layer of AlGaN containing 32.2% of aluminium was replaced by a barrier layer made of a ternary pseudo-alloy:
(AlNn_{AlN}=2/GaNn_{GaN}=4)ₓ₌₇

where:

n_{AlN} is the number of atomic monolayers of AlN,

the thickness of an AlN monolayer is e_{AlN}=0.2485 nm,

n_{GaN} is the number of atomic monolayers of GaN,

the thickness of an GaN monolayer is e_{GaN}=0.2590 nm,

X is the number of periods (AlN n_{AlN}=2/GaN n_{GaN}=4),

Y is the average composition of the barrier:
Y=n_{AlN}/(n_{GaN}+n_{AlN})=32.2%,

E is the equivalent thickness of the barrier:
E=X×(n_{AlN}×e_{AlN}+n_{GaN}×e_{GaN})=20.1 mm.

FIG. 8b illustrates another embodiment of a barrier layer. In this embodiment, a barrier layer of AlGaN containing 50.0% of aluminium was replaced by a barrier layer made of a ternary pseudo-alloy:
(AlNn_{AlN}=1/GaNn_{GaN}=1)ₓ₌₃

FIG. 7b illustrates a semiconducting material 60 made according to a second embodiment of this invention. In this second embodiment, a buffer layer 56 has been inserted between the channel layer 51 and the support 52. The buffer layer 56 is a material chosen from among GaN and AlGaN. This buffer layer facilitates growth of the GaN channel layer. This buffer layer is deposited by bonding or by another known method to those skilled in the art such as an epitaxy method.

In the embodiment illustrated in FIG. 7c, the barrier layer 53 comprises GaN layers 54′, 54″, 54′″ without the same number of atomic monolayers n_{GaN}. Layers 54′, 54″, 54′″ comprise eight, five and two atomic monolayers of GaN, respectively. These layers alternate with AlN layers 55′ and 55″, the layer 55′ being furthest from the support, and the layer 54′″ being closest to the support.

In the illustration of FIG. 7c, the number of atomic monolayers n_{GaN} per layer of GaN 54′, 54″, 54′″ decreases as the distance from the support 52 increases. However, it would be possible to have a barrier layer 53 in which the number of atomic monolayers increases as the distance from the support 52 increases. Thus, the number of atomic monolayers n_{GaN} per GaN layer can vary along the barrier layer 53.

The same is true for the number of monolayers n_{AlN} per AlN layer that can also vary along the barrier layer 53. In the barrier layer, the number of monolayers of GaN and AlN can vary independently as shown in FIG. 7c where the number of atomic monolayers n_{GaN} per layer of GaN 54′, 54″, 54′″ vary whereas the number of atomic monolayers n_{AlN} per layer of AlN 55′ and 55″ do not vary.

The numbers of monolayers n_{GaN} and n_{AlN} can also vary simultaneously along the barrier layer. For example, the number of atomic monolayers n_{AlN} can vary so that it decreases (or increases) as the distance from the support increases, and the number of atomic monolayers n_{GaN} can vary so that it increases (or decreases) as the distance from the support increases. Consequently, the number of atomic monolayers of each layer of binary alloy may vary between a first value on a back face of the barrier layer and a second value on a front face of the barrier layer, the back face being closer to the support than the front face.

FIG. 7d illustrates a semiconducting material according to a fourth embodiment. This semiconducting material includes a support 52, a buffer layer 56, a channel layer 51 and a barrier layer 53. In this embodiment, the buffer layer 56 is a ternary pseudo-alloy of AlGaN composed of alternating layers of binary alloy of GaN 57 and binary alloy of AlN 58. The buffer layer 56 has the same characteristics as the ternary pseudo-alloy barrier layer (n_{GaN} and n_{AlN} between 1 and 40, preferably between 1 and 20, and even more preferably between 2 and 10 and possibly varying along the buffer layer, etc.).

In this embodiment, the buffer layer 56 comprises two GaN layers 57 alternating with two AlN layers 58. Furthermore, the number of atomic monolayers n_{GaN} per GaN layer 57 varies along the buffer layer 56. The GaN layer 57 closest to the support comprises two atomic monolayers while the GaN layer furthest from the support comprises four atomic monolayers. The number of atomic monolayers n_{AlN} per AlN layer 58 can also vary along the buffer layer 56. The GaN layer 57 closest to the support comprises 6 atomic monolayers while the AlN layer furthest from the support comprises three atomic monolayers.

Thus, in the embodiment illustrated in FIG. 7d, the numbers of atomic monolayers per layer of GaN and AlN vary along the buffer layer, the number of atomic monolayers n_{AlN} varying so that it decreases as the distance from the support increases, and the number of atomic monolayers n_{GaN} varies so that it increases as the distance from the support increases.

It is also understood that the numbers of atomic monolayers n_{AlN} and n_{GaN} may be fixed along the buffer layer as was the case for the barrier layer illustrated in FIG. 7a. This buffer layer can be obtained by a production method known to those skilled in the art such as an epitaxy method (molecular beam epitaxy, liquid phase epitaxy, vapour phase epitaxy).

In summary, the barrier layer (53) made of an AlGaN ternary pseudo alloy may be denoted:
(AlNn_{alN}/GaNn_{GaN})ₓ

where:

n_{AlN} is a number of atomic monolayers of an AlN layer where 1≦n_{AlN}≦40, preferably 1≦n_{AlN} 20, more preferably 2≦n_{AlN}≦10) and where n_{AlN} can vary along the barrier layer;

n_{GaN} is a number of atomic monolayers of a GaN layer where 1≦n_{GaN}≦40, preferably 1≦n_{GaN}≦20, more preferably 2≦n_{GaN}≦10) and where n_{GaN} can vary along the barrier layer; and

X is the number of layers of GaN and AlN.

In order to further improve the electronic properties of the semiconducting materials based on III-N, the barrier layer may include one or several layers of ternary alloy in addition to the alternation of layers of binary alloys at the atomic scale. The presence of a layer of ternary alloy in the barrier layer comprising the alternation of layers of binary alloys improves the homogeneity of the piezoelectric field and increases the mobility of charge carriers of the semi-conducting materials. Yet again, the present invention allows an increase electron mobility in the gaz of electrons of μₙ=2090 cm²/V·s for a electron density in the of nₛ=7·10¹² at·cm⁻².

The creation of barrier layer 53 may include the same steps as described above. It is thus possible to start by creating an initial barrier layer by deposit of a layer of a first binary alloy of GaN 54, deposit of a layer of a second binary alloy of AlN 55, and repetition of these deposits steps of layers of GaN and AlN until the required thickness is obtained for the barrier layer 53.

Furthermore, a step of creation of one or several layers of ternary alloy in or on the initial barrier layer is made. The step of creation of layer(s) of ternary alloy varies according to the embodiment of the semi-conducting substrate.

In one embodiment illustrated in FIG. 7e, the barrier layer 53 comprises a layer of ternary alloy 80 of AlGaN and an alternation (at the atomic scale) of layers of a first binary alloy 54 of GaN and of a second binary alloy 55 of AlN. It will be understood that the atomic scale is the scale of angstroms. Each layer of binary alloy of GaN (or AlN) of the alternation comprises between 1 and 40 atomic monolayers of GaN (or AlN), preferably between 1 and 20, and even more preferably between 2 and 10. In all cases, each layer of binary alloy of GaN (or AlN) of the alternation comprises at least one atomic monolayer of this binary alloy of GaN (or AlN).

The alternation of layers of binary alloys 54, 55 of GaN and AlN is located between the layer of the ternary alloy 80 of AlGaN and the support 52. In other words, the layer of the ternary alloy 80 of AlGaN is on top of the alternation of layers of binary alloys of GaN and AlN. The presence of the layer of ternary alloy 80 on top of the alternation of layers of binary alloys 54, 55 of GaN and AlN allows immediate compatibility with the technical methods optimized for semi-conducting materials comprising a barrier layer made of a layer of ternary alloy of AlGaN, especially regarding the making of ohmic contacts, while keeping the benefit of the optimal electronic injection obtained thanks to the alternation at the atomic scale of binary alloys 54, 55 of GaN and AlN in the barrier layer 53.

Indeed, it is important to have an ordered alloy in the barrier layer 53 that decreases as the distance from the interface between the barrier layer and the channel layer 51 increases. In other words, a semi-conducting material having an alloy disorder in a layer located far from the interface between the channel layer 51 and the barrier layer 53 has a better mobility of the charge carriers and a piezoelectric polarization field more homogeneous than a semi-conducting material having an alloy disorder in a layer located closed to the interface between the channel layer 51 and the barrier layer 53

The step of creation of the layer of ternary alloy 80 of AlGaN, allowing the semi-conducting material shown in FIG. 7e to be obtained, comprises the deposit of a classical layer of ternary alloy created by epitaxy. It will be understood, in the present invention, that a “classical layer of ternary alloy” is a layer of ternary alloy created by epitaxy by making interact in a low residual pressure room (ultra-high vacuum, residual pressure comprised between 10⁻⁹ Torr and 10⁻¹⁴ Torr) atomic or molecular flows (obtained by evaporation of solid sources or by direct injection of gas precursors of GaN and AlN) on the substrate heated to an appropriate temperature for the epitaxial growth.

In another embodiment shown in FIG. 7f, the barrier layer 53 comprises a plurality of layers of ternary alloy 70 of AlGaN. Those layers of ternary alloy 70 of AlGaN are located in the alternation of layers of binary alloys 54, 55 of GaN and AlN. The layers of ternary alloy 70 of AlGaN interbedded in the alternation of layers of binary alloys 54, 55 of GaN and AlN are obtained by interdiffusion of the III elements of the layers of binary alloys 54, 55 of GaN and AlN.

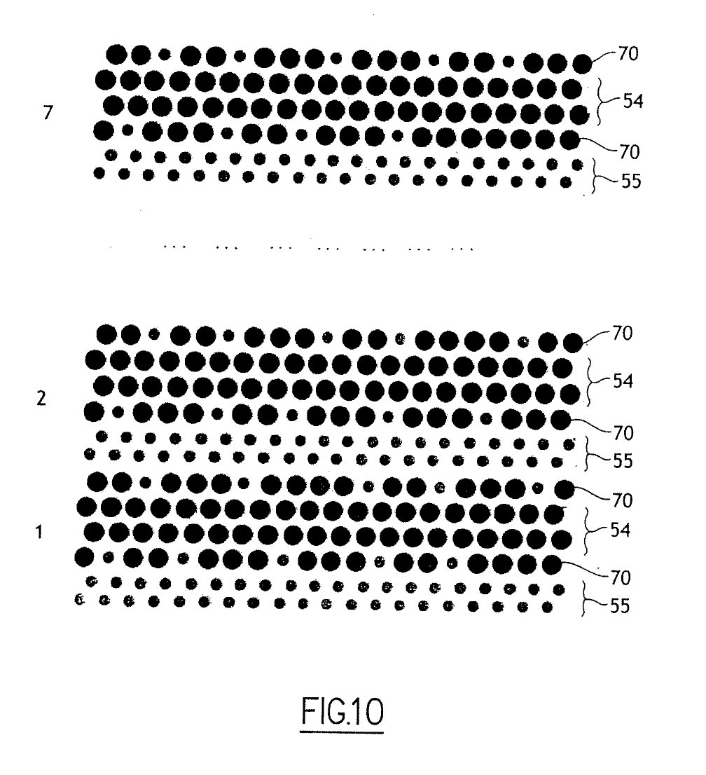

FIG. 10 is a sectional view, at the atomic scale, of the barrier layer from the embodiment illustrated in FIG. 7f. Each layer of binary alloy of GaN (or AlN) comprises two atomic monolayers. Each layer of ternary alloy of AlGaN comprises one atomic monolayer of ternary alloy. The presence of layers of ternary alloy 70 between the layers of binary alloys 54, 55 allows avoiding the violent variations of composition in the barrier layer 53. This improves the homogeneity of the local piezoelectric polarisation field. This homogenisation of the polarisation field allows decreasing the charge density fluctuations at the interface between the channel layer 51 and the barrier layer 53.

The creation of the plurality of layers of ternary alloy 70 illustrated in FIG. 7f comprises a thermal treatment after having created at least one alternation of layers of binary alloys 54, 55 of GaN and AlN deposited for the creation of the barrier layer 53. The thermal treatment can be realised at the end of the step of creation of the barrier layer 53 (that is to say after the successive deposit steps of the layers of the first binary alloy 54 of GaN and the second binary alloy of AlN).

This treatment can also be realized during the steps of creating the barrier layer. In that case, the thermal treatment is carried out before some deposit steps of the second binary alloy. For example, one can begin to deposit the first binary alloy (GaN). Then, one can deposit the second binary alloy (AlN). Then, on can carry out the thermal treatment which allows better inter-diffusion of the III elements of the layers of binary alloys 54, 55 of GaN and AlN. The diffusion, very local, can take place on a typical distance of 1 to 5 material monolayers.

The thermal treatment is carried out after at least some binary alloy deposits. Typical conditions for this treatment are:

at a surface temperature between 0° C. and 300° C. above to the temperature of creation of monolayers of first and second binary alloys;

under vacuum or ultra-high vacuum between 10⁻⁸ Torr and 10⁻¹ Torr;

under a gas mixture flow comprising ammoniac NH3 or nitrogen molecule N2 or hydrogen molecule H2 a pressure comprised between 10⁻⁸ Torr and the pressure of 1 kBar;

in presence of a NH3, N2 or H2 plasma.

A layer of ternary alloy 70 of AlGaN is then obtained, located between the layers of the first and second binary alloys of GaN and AlN. This layer of ternary alloy comprises between 1 and 5 monolayers of ternary alloy.

If the barrier layer thickness does not correspond to the required thickness, a deposit of a layer of GaN is made and a deposit of a layer of AlN is made. Then, the thermal treatment is carried out, and so on until the thickness corresponds to the required thickness. The thermal treatment can be carried out systematically after each deposit of a layer of the second binary alloy. For example, the thermal treatment can be made once on two times. That is to say the thermal treatment is carried out after two deposits of a layer of a binary alloy have been made. The thermal treatment may also be carried out only once at the end of the creation step of the initial barrier layer, that is to say once the required barrier layer thickness is obtained. Moreover, before carrying out the thermal treatment, it is possible to deposit an additional layer of AlN or SiN in order to stabilize the surface of the barrier layer 53 during the thermal treatment.

In FIG. 7g, a semi-conducting material according to another embodiment of the present invention is shown. In this embodiment, the semi-conducting material comprises the same elements as the embodiment illustrated in FIG. 7. Those same elements are the alternation of layer of binary alloys 54, 55 of GaN and AlN, and the plurality of layers of the ternary alloy 70 located in the alternation. Moreover, the embodiment illustrated in FIG. 7g comprises a classical layer of ternary alloy 80 on top of the alternation. This allows gathering the advantages of the embodiments illustrated in FIGS. 7e and 7f.

The skilled artisan will appreciate that it is possible to realize a semi-conducting material comprising a channel layer or a buffer layer comprising the same elements (layers alternation of binary alloys, etc.) than those described for the barrier layer. Having a channel layer or a buffer layer made of ternary pseudo-alloy allows increasing the homogeneity of the distribution of the electrons in the semi-conducting material.

FIG. 9 shows an example of semi-conducting material realization according to the present invention. In this example, the semi-conductor comprises:

a Si (silicon) substrate 52,

a buffer layer 56 made of a Al_{0.1}Ga_{0.9}N alloy, a channel layer 51 made of a In_{0.25}Ga_{0.75}N ternary pseudo-alloy of a thickness of 155 Angstroms,

an alternation of layer of binary alloys 54, 55 made of ternary pseudo-alloy Al_{0.32}Ga_{0.68}N of a thickness of 184 Angstroms,

a layer of a classical ternary alloy 80 of Al_{0.4}Ga_{0.6}N of a thickness of 50 Angstroms,

a layer of binary alloy 190 of GaN of a thickness of 20 Angstroms, a layer of binary alloy 100 of AlN of a thickness of 30 Angstroms.

In the different embodiments illustrated in FIGS. 7a to 7g, the channel layer is made of binary alloy of GaN. In other embodiments, the channel layer is a ternary pseudo-alloy of AlGaN, or InGaN, or AlBN, or InBN, or InAlN.

In these other embodiments, the channel layer is created using a similar method to the one described for the creation of the barrier layer, and the binary alloys for making the ternary pseudo-alloy are chosen from among AlN, GaN, BN, and InN. When the channel layer is made of a ternary pseudo-alloy, it comprises the same features as the ternary pseudo-alloy barrier layer (number of atomic monolayers per layer of binary alloy comprised between 1 and 40, preferably between 1 and 20, and more preferably between 2 and 10, this number being able to vary along the thickness of the channel layer). By having a channel layer made of ternary pseudo-alloy, the homogeneity of the semi-conducting material (and particularly the distribution of electrons) is increased. The surface morphology of AlGaN/GaN HEMT structure is generally affected by Al concentration in the barrier.

The semi-conducting material according to the invention allows increasing the aluminium concentration in the barrier layer (or channel layer, or buffer layer) as illustrated in FIG. 11. Indeed, by decreasing the roughness at the interface between the channel layer and the barrier layer, it is possible to increase the concentration of Al in the layer.

In fact, the perturbations (homogeneity of the electronic density . . . ) in a layer are principally due to the Al atoms. Hence, for a given roughness, it is possible with the present invention to increase the concentration of aluminium.

OK data points of FIG. 11 correspond to structures according to the present invention which are grown on Si 111 substrates for different thicknesses and aluminium concentrations measured by XRD. As shown in FIG. 11, thick barrier layers are achievable (up to 41 nm for 23% aluminium), but most results correspond to thin barrier layers. Typical thicknesses ranging between 20 nm and 27 nm have shown best results after device fabrications.

Below 25 nm, aluminium concentration in the 28%-30% range is a standard specification leading to optimised ohmic contacts. For higher Al concentrations (32% and more), barrier thickness must be decreased down to 15-20 nm.

Cross Hatch data points of FIG. 11 correspond to cross-hatched structures according to the present invention for different thicknesses and Aluminium concentrations measured by XRD. In this case, relaxation of the AlGaN barrier occurs, leading to micro-cracks on the surface.

This strain effect appears when aluminium concentration is to high in regards with barrier thickness. The trend is given by curve 500. Barrier layer thickness/Al % below this curve 500 are preferred for use.

PSP data points correspond to pseudomorphic structures according to the present invention with strained GaN channel on A_{l0.1}Ga_{0.9}N buffer layer. As shown in FIG. 11, it is possible, with such pseudomorphic structures, to reach concentrations of 40% in Aluminium even for thick barriers (26 nm).

FIGS. 12E to 121 illustrate the surface morphology of different structures according to the present invention with various aluminium concentrations in the AlGaN barrier. FIG. 12E shows a structure according to the present invention having an Aluminium concentration of 20% in the AlGaN barrier of a thickness equal to 25 nm. FIG. 12F shows a structure according to the present invention having an Aluminium concentration of 25% in the AlGaN barrier of a thickness equal to 25 nm. FIG. 12G shows a structure according to the present invention having an aluminium concentration of 32% in the AlGaN barrier of a thickness equal to 25 nm. FIG. 12H shows a structure according to the present invention having an aluminium concentration of 40% in the AlGaN barrier of a thickness equal to 25 nm. FIG. 121 shows a structure according to the present invention having an aluminium concentration of 39% in the AlGaN barrier of a thickness equal to 26 nm.

As is shown on FIGS. 12E to 121, no differences are observed on the surface morphology for every layers. In the different embodiments illustrated in FIGS. 7a to 7g, the barrier layer is a ternary pseudo-alloy of AlGaN. In other embodiments, the barrier layer is a ternary pseudo-alloy of InGaN (indium gallium nitride), or AlBN (aluminium boron nitride), or InBN (indium boron nitride, or InAlN (indium aluminium nitride). In these other embodiments, the first and second binary alloys making the ternary pseudo-alloy are chosen from among AlN, GaN, BN, and InN.

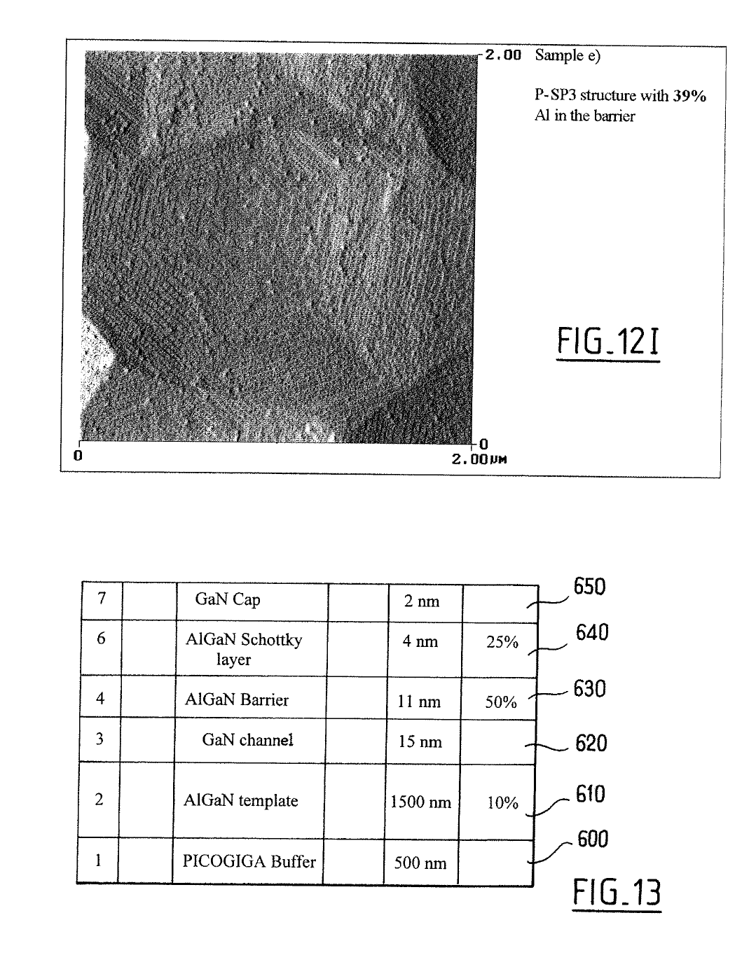

FIG. 13 shows another embodiment according to the present invention. This embodiment comprises:

a substrate 600 having a thickness of 500 nm,

an AlGaN template layer 610 having a thickness of 1500 nm which comprises 10% of aluminium in concentration,

a GaN channel layer 620 having a thickness of 15 nm,

a barrier layer 630 having a thickness of 11 nm which comprises 50% of Aluminium in concentration,

an AlGaN Schottky layer 640 having a thickness of 4 nm which comprises 25% of aluminium in concentration, and

a GaN cap layer 650 having a thickness of 2 nm.

The barrier layer of the semi-conducting material illustrated in FIG. 13 comprises alternations of one monolayer of AlN (one monatomic plane of Al and one monatomic plane of N) and one monolayer of GaN (one monatomic plane of Ga and one monatomic plane of N).

The present invention presents some advantages thanks to the use of monolayers, which allows obtaining ordered ternary pseudo-alloy, as AlGaN layer having a concentration of 50% of Aluminium (Al—N—Ga—N).

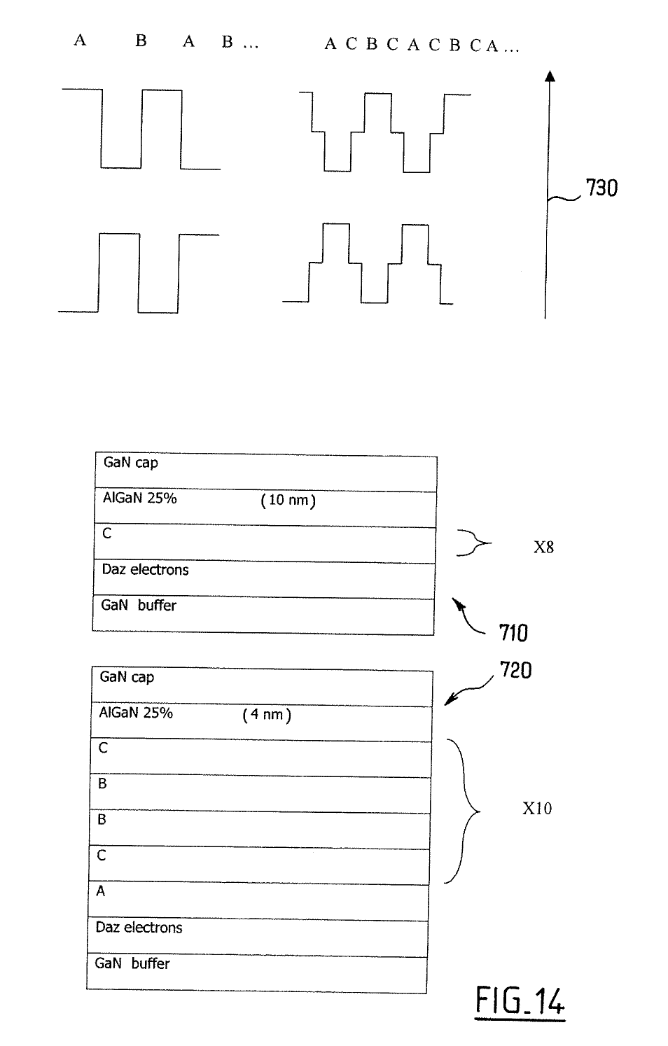

FIG. 14 shows some advantages of the present invention compared to the process and device described in WO02/093650. In FIG. 14:

A represents an AlN lattice cell (Al—N—Al—N),

B represents a GaN lattice cell (Ga—N—Ga—N), and

C represents an AlGaN lattice cell (Al—N—Ga—N).

As can be observed with the alternation C-A-C—B . . . according to the present invention and illustrated on the top of FIG. 14, the present invention allows smoothing of the forbidden band diagram 730:

the energy diagram is smoothed (Eg is the energy of the forbidden band of the alloys: Eg(GaN)=3.4 eV, Eg(AlN)=6.2 eV, Eg(AlGaN 50%)=4.8 eV,

the strain, in the structure presents a better distribution which allows to obtain more reliable transistor structures.

On the contrary, the process and device described in WO02/093650 does not allow smoothing of the forbidden band diagram 730. Indeed, the process described in WO02/093650 does not allow obtaining an AlGaN lattice cell C (Al—N—Ga—N) (since the “monolayers” as defined in WO02/093650 are too thick). Hence, the process described in WO02/093650 only allows obtaining alternations A-B-A-B . . . as illustrated on top of FIG. 14.

Embodiments 710 and 720 are two examples of semi-conducting material according to the present invention which comprise C layers.

Although some example embodiments of the invention were described in detail above, those skilled in the art will easily understand that many modifications could be made without physically going outside the scope of the disclosure and the advantages described herein. For example, in other embodiments, the nitride element could be replaced by any other element in column V (P, As, etc.) of the periodic table of elements. Consequently, all modifications of this type will be included in the scope of this invention as defined in the attached claims.

What is claimed is:

1. A piezoelectric structure comprising a semi-conducting substrate based on elements in Groups III and nitrogen of the periodic table, including a support, a channel layer on the support and a barrier layer on the channel layer, wherein the barrier layer is composed of, on an atomic scale, alternating layers of first and second Group III-N binary semi-conducting alloys.

2. The substrate of claim 1, wherein the channel layer is composed of, on an atomic scale, alternating layers of third and fourth Group III-N binary semi-conducting alloys.

3. The substrate of claim 2, wherein the semi-conducting substrate further includes a buffer layer between the support and the channel layer, the buffer layer is composed of, on an atomic scale, alternating layers of fifth and sixth Group III-N binary semi-conducting alloys.

4. The substrate of claim 3, wherein the number of monolayers in each set of alternating layers of the barrier layer, the channel layer or the buffer layer is between 1 and 20 and the binary alloys are perfectly ordered along a preferred crystalline axis.

5. The substrate of claim 3, wherein the number of monolayers in each set of alternating layers of the barrier layer, the channel layer or the buffer layer varies between a first value on a back face of the barrier layer or of the channel layer or of the buffer layer, and a second value on a front face of the barrier layer, the channel layer or the buffer layer, the back face(s) being closer to the support than the front face.

6. The substrate of claim 5, wherein the first and second values are between 1 and 20 and the first value is greater than the second value and all binary alloys are perfectly ordered along a preferred crystalline axis.

7. The substrate of claim 5, wherein the first, second, third, fourth, fifth and sixth binary alloys are the same or different and are AlN, GaN, BN, or InN.

8. The substrate of claim 1, wherein the barrier layer further includes a layer of a Group III-N semi-conducting ternary alloy.

9. The substrate of claim 8, wherein the alternating layers of first and second Group III-N semi-conducting binary alloys are located between the support and the layer of Group III-N semi-conducting ternary alloy.

10. The substrate of claim 8, wherein the barrier layer comprises a plurality of layers of Group III-N semi-conducting ternary alloy, with each layer of the Group III-N semi-conducting ternary alloy being located between a layer of the first binary alloy and a layer of the second binary alloy.

11. The substrate of claim 10, wherein the barrier layer further comprises a layer of the Group III-N semi-conducting ternary alloy on the layers of the first and second Group III-N semi-conducting binary alloys.

12. The substrate of claim 2, wherein the channel layer further comprises a plurality of layers of Group II-N semi-conducting ternary alloy, with each layer of the Group III-N semi-conducting ternary alloy being located between a layer of the third binary alloy and a layer of the fourth binary alloy.

13. The substrate of claim 8, wherein each layer of the ternary alloy includes between 1 and 5 atomic monolayers.

14. The substrate of claim 3, wherein the channel layer is made of a layer of ternary alloy of AlGaN, or InGaN, or AlBN, or InBN, or InAlN.

15. The substrate of claim 1, wherein the channel layer is made of a layer of binary alloy of GaN, or AlN, or BN, or InN.

16. The substrate of claim 1, wherein the semi-conducting substrate further comprises a buffer layer between the support and the channel layer, with the buffer layer being made of a layer of binary alloy of GaN, or AlN, or BN, or InN.

17. The substrate of claim 1, wherein the semi-conducting substrate further comprises a buffer layer between the support and the channel layer, with the buffer layer being made of a layer of ternary alloy of AlGaN, or InGaN, or AlBN, or InBN, or InAlN.

18. The substrate of claim 1, wherein the support is made of Si, SiC, AlN, Sapphire, or GaN.

19. The substrate of claim 1, wherein the barrier layer has a thickness of between 2 nm and 500 nm.

20. A method for preparation of a piezoelectric structure comprising a semi-conducting substrate that includes a support, a channel layer on the support and a barrier layer on the channel layer, which comprises creating the barrier layer by depositing at least one atomic monolayer of a first binary alloy; depositing at least one atomic monolayer of a second binary alloy; and repeating the depositing as necessary until a desired thickness is obtained.

21. The method of claim 20, which further comprises creating at least one layer of ternary alloy in or on the barrier layer.

22. The method of claim 21, wherein creating the ternary alloy layer comprises depositing a layer of a ternary alloy on the barrier layer.

23. The method of claim 21, wherein creating the ternary alloy layer comprises thermally treating the atomic monolayers of the first and second binary alloys to form the ternary layer.

24. The method of claim 23, wherein the thermally treating is carried out after at least some depositing of the second binary alloy:
at a surface temperature between 0° C. and 300° C. above to the temperatures where the first and second binary alloy monolayers are created;
under vacuum or ultra-high vacuum between 10⁻⁸ Torr and 10⁻¹ Torr;
under a gas mixture flow comprising ammonia, nitrogen or hydrogen at a pressure comprised between 10⁻⁸ Torr and 1 kBar; or
in the presence of an ammonia, nitrogen or hydrogen plasma.

25. The method of claim 23, wherein thermally treating the first and second binary alloy monolayers is conducted after creating the initial barrier layer.

26. The method of claim 20, which further comprises creating the channel layer by depositing a binary alloy of GaN, or AlN, or BN, or InN wherein the binary alloys are perfectly ordered along a preferred crystalline axis.

27. The method of claim 20, which further comprises creating the channel layer by depositing a ternary alloy of AlGaN, or InGaN, or AlBN, or InBN, or InAlN.

28. The method of claim 20, which further comprises creating the channel layer by depositing an atomic monolayer of a third binary alloy; depositing an atomic monolayer of a fourth binary alloy; and repeating the depositing as necessary until a desired thickness is obtained.

29. The method of claim 28, wherein the creating of the channel layer comprises thermally treating the third and fourth binary alloy monolayers before depositing the fourth binary alloy:
at a surface temperature between 0° C. and 300° C. above to the temperature of creation of monolayers of third and fourth binary alloys;
under vacuum or ultra-high vacuum between 10⁻⁸ Torr and 10⁻¹ Torr;
under a gas mixture flow comprising ammonia, nitrogen or hydrogen at a pressure comprised between 10⁻⁸ Torr and 1 kBar; or
in the presence of an ammonia, nitrogen or hydrogen plasma.

30. The method of claim 20, which further comprises creating the buffer layer by depositing a binary alloy of GaN, or AlN, or BN, or InN wherein the binary alloys are perfectly ordered along a preferred crystalline axis.
